(19) United States
(12) Patent Application Publication
(10) Pub. No.: US 2026/0312360 A1
(43) Pub. Date: Oct. 8, 2026

(54) OPTOELECTRONIC MODULE AND METHOD FOR PRODUCING AN OPTOELECTRONIC MODULE

(71) Applicant: Ams-OSRAM International GmbH, Regensburg (DE)

(72) Inventors: Jörg Erich Sorg, Regensburg (DE); Erik Heinemann, Regensburg (DE); Thomas Kippess, Neumarkt (DE)

(21) Appl. No.: 18/996,656

(22) PCT Filed: Jul. 24, 2023
(86) PCT No.: PCT/EP2023/070425

§ 371 Date: Jan. 17, 2025

(30) Foreign Application Priority Data
Jul. 29, 2022 (DE) 10 2022 119 151.6

(51) Int. Cl. H01S 5/02355; H01S 5/0225; H01S 5/02315

(52) U.S. Cl. CPC H01S 5/02355; H01S 5/0225; H01S 5/02315

(57) ABSTRACT

In an embodiment an optoelectronic module includes a carrier, a radiation-emitting semiconductor body arranged on the carrier and an optical element in a beam path of the semiconductor body, wherein at least the optical element is connected to the carrier via a connection site including metallic nanostructures.

### CROSS-REFERENCE TO RELATED APPLICATIONS

This patent application is a national phase filing under section 371 of PCT/EP2023/070425, filed Jul. 24, 2023, which claims the priority of German patent application no. 102022119151.6, filed Jul. 29, 2022, each of which is incorporated herein by reference in its entirety.

### TECHNICAL FIELD

An optoelectronic module and a method for producing an optoelectronic module are disclosed.

### SUMMARY

Embodiments provide an optoelectronic module with increased efficiency and/or with an extended service life. Further embodiments provide an efficient and simple method for producing an optoelectronic module.

According to at least one embodiment, the optoelectronic module comprises a carrier. The carrier serves in particular to mechanically stabilize further components of the optoelectronic module. It is also possible for the further components to be electrically contacted via the carrier. The carrier can, for example, be a connection carrier that comprises conductor paths and/or contact sites for the electrical contacting of further components.

According to at least one embodiment, the optoelectronic module comprises a radiation-emitting semiconductor body. In other words, the optoelectronic module is in particular a radiation-emitting module. Preferably, the radiation-emitting semiconductor body emits electromagnetic radiation in the visible spectral range, for example in the red, green or blue wavelength range, and/or in the near infrared or UV spectral range. In particular, the semiconductor body is a laser diode. In particular, the semiconductor body comprises an exit facet through which the electromagnetic radiation is emitted.

Preferably, the radiation-emitting semiconductor body is arranged on the carrier. The carrier can advantageously be used for electrical contacting of the radiation-emitting semiconductor body.

According to at least one embodiment, the optoelectronic module comprises an optical element. In particular, the optical element is arranged in a beam path of the radiation-emitting semiconductor body. For example, the optical element is configured to influence the electromagnetic radiation emitted by the radiation-emitting semiconductor body. The optical element may, for example, be a diffractive and/or reflective and/or radiation-refracting and/or polarizing and/or birefringent optical element.

According to at least one embodiment, at least one component from the group semiconductor body and optical element is connected to the carrier via a connection site. In particular, the connection site is configured to mechanically and/or electrically couple the component to the carrier. For example, the connection site is in direct contact with the carrier, the semiconductor body and/or the optical element. Alternatively, it is possible that a further component is arranged between the semiconductor body and the carrier and/or the optical element and the carrier, which is in direct contact with the connection site. For example, a submount is arranged between the semiconductor body and the carrier, wherein the submount is connected directly to the carrier via the connection site, for example.

The connection site comprises metallic nanostructures. The nanostructures thus comprise a metal or are formed from it. For example, the nanostructures comprise metallic properties. In particular, the nanostructures comprise an extension, for example a length, a width, and/or a diameter, in the range of between and including 10 nanometers and 10 micrometers, in particular in the range of between and including 10 nanometers and 1 micrometer.

In particular, the connection site is free of organic constituents. In other words, no organic bonding agent, for example no organic adhesive, is used to attach the radiation-emitting semiconductor body and/or the optical element to the carrier.

According to at least one embodiment, an optoelectronic module comprises a carrier, a radiation-emitting semiconductor body on the carrier and an optical element in a beam path of the semiconductor body, wherein at least one component from the group semiconductor body and optical element is connected to the carrier via a connection site comprising metallic nanostructures. In particular, the semiconductor body and the optical element are each connected to the carrier via a connection site.

Such an optoelectronic module can advantageously be used in the field of projection, in the automotive sector, such as in a head-up display (HUD) or in a lidar system, and/or in the field of sensor technology.

According to at least one embodiment, the optoelectronic module comprises a housing. In particular, the housing hermetically encapsulates the semiconductor body.

Advantageously, the housing at least partially prevents the semiconductor body from being damaged by external influences, such as oxygen or moisture. This can extend the service life of the optoelectronic module.

According to at least one embodiment, the semiconductor body comprises or is a laser diode. In particular, the laser diode emits an emission spectrum with an emission maximum of at most 550 nanometers or with an emission maximum in the range of between and including 550 nanometers and 620 nanometers or in the range of between and including 620 nanometers 680 nanometers. In other words, the laser diode emits, for example, blue to blue-green light, green to green-yellow light or red light.

According to at least one embodiment, the optoelectronic module comprises at least one further semiconductor body. All features and embodiments already described in connection with the semiconductor body also apply in particular to the at least one further semiconductor body.

In particular, the optoelectronic module comprises a total of three semiconductor bodies. The at least one further semiconductor body is or comprises, for example, a laser diode. Preferably, the further semiconductor bodies comprise an emission maximum in a different spectral range than the semiconductor body. For example, the optoelectronic module comprises a first semiconductor body with an emission maximum in the blue spectral range, a second semiconductor body with an emission maximum in the green spectral range and a third semiconductor body with an emission maximum in the red spectral range. In this way, an optoelectronic module can be provided that emits white mixed light.

According to at least one exemplary embodiment, the optoelectronic module is free of organic constituents at least within the housing.

In optoelectronic modules, which comprise in particular a laser diode with an emission maximum of at most 550 nanometers, it is possible that organic contaminations are deposited on the exit facet of the semiconductor body due to a high energy density of the emitted radiation and/or a high beam divergence. This can lead to a reduced service life of the optoelectronic module. As the optoelectronic module is formed free of organic constituents, at least within the housing, the reduced service life of the optoelectronic module due to the contaminations on the exit facet of the semiconductor body is in particular prevented.

According to at least one embodiment of the optoelectronic module, the optical element is selected from the following group: lens, prism, collimating lens, beam combiner, polarization filter, birefringent crystal, photonic integrated circuit. In particular, the beam combiner is a dichroic beam combiner. In English, the photonic integrated circuit is known as a “photonic integrated circuit” (short PIC).

According to at least one embodiment of the optoelectronic module, the metallic nanostructures comprise or consist of nanowires.

According to at least one embodiment of the optoelectronic module, the nanowires comprise a distance of at most 10 micrometers, in particular at most 1 micrometer, for example at most 0.1 micrometer. In particular, the distance is the length of a shortest straight connecting line between two neighboring nanowires.

According to at least one embodiment of the optoelectronic module, the nanowires at least partially touch each other. In other words, the nanowires are present in the connection site in such a way that there is stable contact between two nanowires. This advantageously creates a mechanically stable connection site. In particular, the nanowires are interlocked.

According to at least one embodiment of the optoelectronic module, the metallic nanostructures comprise or consist of at least one metal from the following group: Au, Ag, Cu. In particular, Au, Ag and Cu are characterized by their chemical stability. In addition, these metals can be easily deformed.

According to at least one embodiment of the optoelectronic module, an alloy is arranged between the metallic nanostructures. In particular, the alloy comprises the metal of the nanostructures. In particular, the alloy provides a firmly bonded connection site.

According to at least one embodiment of the optoelectronic module, a further constituent of the alloy is selected from the following group: Ga, In, Hg, Sn. In particular, Ga, In, Hg and Sn comprise a low melting point in their metallic form. As a result, these elements can advantageously be easily introduced into the connection site. Furthermore, Ga, In, Hg, and Sn form alloys with the metal of the nanostructures, for example Au, Ag and Cu, with a melting point of in particular over 250° C., preferably over 260° C. This advantageously provides an optoelectronic module that comprises a high temperature resistance and/or is SMD solderable. SMD stands here and in the following for surface mounted device.

According to at least one embodiment of the optoelectronic module, the alloy comprises a material selected from the following group: AuGa, AuIn, AuHg, AgGa, AgIn, AgHg, CuSn.

A method for producing an optoelectronic module is further disclosed. In particular, the optoelectronic module described herein is produced using the method. Therefore, all features and embodiments described in connection with the optoelectronic module also apply to the method and vice versa.

According to at least one embodiment of the method, a carrier with a first connection element is provided. In particular, the connection element comprises metallic nanostructures. For example, the metallic nanostructures comprise or consist of nanowires. The first connection element covers the carrier, for example partially or completely.

According to at least one embodiment of the method, a component is provided. The component comprises a second connection element comprising metallic nanostructures. In particular, the metallic nanostructures comprise or consist of nanowires. The metallic nanostructures of the first connection element and the metallic nanostructures of the second connection element are, for example, formed the same or differently. The second connection element at least partially covers a surface of the component that will be connected with the carrier.

According to at least one embodiment of the method, the component is actively adjusted on the carrier. During the active adjustment of the component, the component is in particular positioned and/or aligned on the carrier using an optical output parameter. For example, an intensity, a spectral power distribution, a beam divergence and/or a degree of polarization of an electromagnetic radiation emitted by the optoelectronic module during operation is used as an optical output parameter. Positioning is understood here and in the following to mean, for example, a displacement of the component in a lateral and/or horizontal direction relative to a main extension plane of the carrier. The alignment of the component comprises in particular a rotation of the component about one of its main axes. In particular, the component is aligned around six axes during active adjustment.

Advantageously, the active adjustment enables precise mounting of the component on the carrier. This allows component-specific fluctuations to be compensated for, thus preventing the production of defective optoelectronic modules.

According to at least one embodiment of the method, the carrier and the component are connected. In particular, this creates a connection site. In particular, the connection site comprises the first connection element and the second connection element. For example, the carrier and the component are already connected during the active adjustment of the component on the carrier. Alternatively, it is possible for the carrier and the component to be connected only after active adjustment. If the metallic nanostructures comprise nanowires, the nanowires of the first connection element and the second connection element interlock, particularly during connecting.

According to at least one embodiment, the method for producing an optoelectronic module comprises the following steps:
providing a carrier with a first connection element comprising metallic nanostructures,
providing a component with a second connection element comprising metallic nanostructures,
active adjustment of the component on the carrier,
connecting the carrier and the component, wherein a connection site comprising the first connection element and the second connection element is formed.

In particular, the connection site comprising the first connection element and the second connection element is free of organic constituents, which can initially lead to reduced performance and ultimately to inoperability of the optoelectronic module. The connection site comprising no organic constituents can therefore advantageously extend the service life of the optoelectronic module.

In other methods for producing optoelectronic modules, organic adhesives are used to connect the component and the carrier. However, when using the organic adhesive, it is necessary to first actively adjust the component without applying the organic adhesive, remove the component again, apply the organic adhesive, move the component to the previously determined position and then cure the organic adhesive. In the method described here, the component is advantageously only brought into the desired position once by active adjustment and bonded to the carrier. As a result, the number of optoelectronic modules that can be produced using the method in one hour can be increased compared to the other methods.

According to at least one embodiment of the method, the component is selected from the following group: semiconductor body, optical element, submount, interposer. In particular, a submount is a component that is used for electrical contacting and/or mechanical stabilization of a semiconductor body. An interposer is, for example, a mechanical component that can be used to adjust the height of the optical element.

According to at least one embodiment of the method, the connection site is stable at a temperature of at least 250° C. By stable is understood here and in the following that the connection site shows no or only slight mechanical deformation and/or chemical change of a composition of the connection site at the temperature. In other words, the connection site comprises a high temperature resistance. This makes it possible to provide an optoelectronic module that is advantageously SMD-solderable.

According to at least one embodiment of the method, a compacting agent is introduced into the connection site during connecting the carrier and the component. The compacting agent forms an alloy with a material of the first connection element and the second connection element. Preferably, the compacting agent forms an alloy with a material of the metallic nanostructures.

During introducing of the compacting agent, the material of the first connection element and the second connection element in particular is partially dissolved in the compacting agent, thus forming the alloy. The alloy preferably comprises a higher melting point than the compacting agent. This can lead to isothermal solidification of the alloy. The melting point of the alloy also allows the alloy to harden at low temperatures, for example at temperatures below 100° C. The fact that the material of the first connection element and the second connection element is only partially dissolved in the compacting agent means that the connection site with the metallic nanostructures can be distinguished from a soldered joint. For example, a difference between the connection site and a solder joint can be seen using a scanning electron microscope.

Advantageously, the compacting agent and thus also the alloy fills cavities that are present in particular between the metallic nanostructures of the first connection element and the metallic nanostructures of the second connection element. This advantageously forms a firmly bonded connection between the component and the carrier.

In other optoelectronic modules, a solder is used in particular for a firmly bonded connection of the carrier and the component. The use of the solder can lead to a high thermal and/or mechanical load on the carrier and/or the component. The high thermal and/or mechanical load is caused, for example, by high temperatures that are necessary during soldering or by stresses and distortion that occur during soldering. In addition, it is possible that a solder material used, such as a solder paste, contains an organic constituent that must be removed to protect the optoelectronic module from contamination.

When using the first connection element and the second connection element together with the compacting agent, a high thermal and/or mechanical load on the optoelectronic module is advantageously prevented. Furthermore, the connection site created in this way is in particular free of organic constituents and comprises low frozen-in stresses as well as a low bi-metal effect.

The bi-metal effect can be observed, for example, in two superimposed layers of metals that are bonded together and comprise different coefficients of thermal expansion. Due to the different coefficients of thermal expansion, one of the layers expands more than the other when heated, causing the two superimposed layers to bend.

According to at least one embodiment of the method, the nanowires in the first connection element and the nanowires in the second connection element are brought together during the active adjustment such that the nanowires of the first connection element and the nanowires of the second connection element comprise a distance of at most 10 micrometers, in particular of at most 1 micrometer, for example of at most 0.1 micrometer. In particular, therefore, a backlash-free active adjustment is carried out. A mechanically stable connection site is then obtained after the compaction agent has been inserted, for example.

According to at least one embodiment of the method, the compacting agent is melted before being introduced into the connection site. In other words, the compacting agent is introduced into the connection site in liquid form. In this way, in particular, an almost complete or complete filling of the cavities between the metallic nanostructures of the first connection element and the metallic nanostructures of the second connection element with the compacting agent and the alloy is achieved.

According to at least one embodiment of the method, the compacting agent is selected from the following group: Ga, In, Hg, Sn and alloys thereof. In particular, Ga, In, Hg, Sn and alloys thereof comprise a low melting point. This advantageously facilitates introduction into the connection site. In addition, thermal load on the optoelectronic module and its components can be reduced.

According to at least one embodiment of the method, the first connection element comprises a larger extension than the second connection element, in particular in a plan view. In particular, the first connection element comprises a larger area in plan view than the second connection element. This advantageously achieves the formation of a connection site with the largest possible expansion, for example with the expansion of the second connection element.

According to at least one embodiment of the method, the first connection element and/or the second connection element comprises, in particular in plan view, a rectangular, in particular square, shape. However, it is also possible that the first connection element and/or the second connection element comprise, in plan view, another shape, such as that of an oval, in particular an ellipse or a circle, or that of a polygon, such as a hexagon.

### BRIEF DESCRIPTION OF THE DRAWINGS

Further advantageous embodiments, designs, and further developments of the optoelectronic module and of the method for producing an optoelectronic module are shown in the following exemplary embodiments illustrated in conjunction with the figures.

FIG. 1A shows a schematic sectional view of an optoelectronic module according to an exemplary embodiment;

FIG. 1B shows a schematic plan view of an optoelectronic module according to an exemplary embodiment;

FIGS. 2A and 2B show schematic sectional views of steps of a method for producing an optoelectronic module according to an exemplary embodiment;

FIGS. 3A to 3C show schematic sectional views of steps of a method for producing an optoelectronic module according to a further exemplary embodiment; and

FIGS. 4A and 4B show a schematic sectional view and a plan view of a step of a method for producing an optoelectronic module according to an exemplary embodiment.

Elements that are identical, similar, or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

### DETAILED DESCRIPTION OF ILLUSTRATIVE EMBODIMENTS

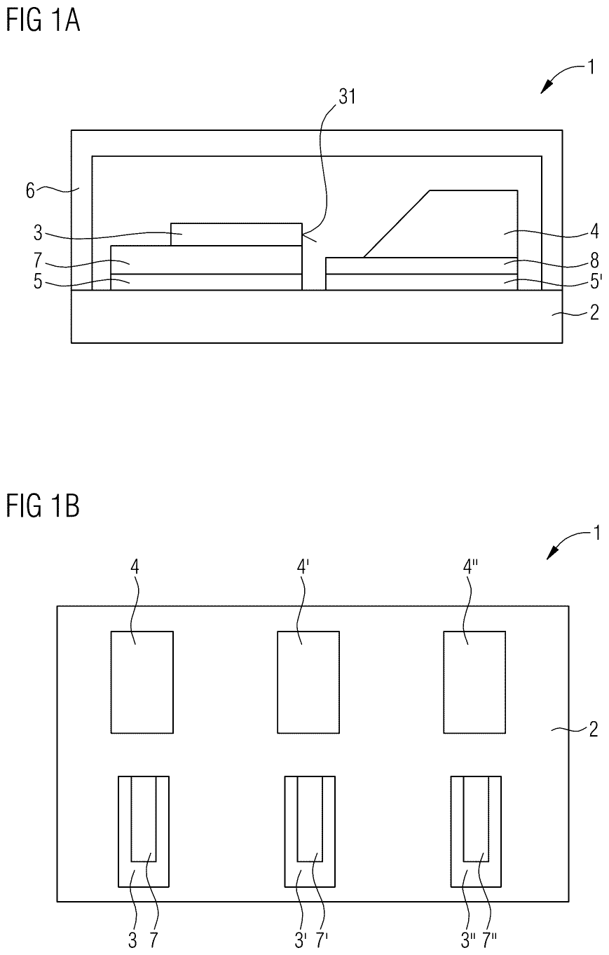

In FIG. 1A an exemplary embodiment of an optoelectronic module 1 is shown. The optoelectronic module 1 comprises a carrier 2 on which a semiconductor body 3 and an optical element 4 are arranged. The semiconductor body 3 and the optical element 4 are hermetically encapsulated by a housing 6.

The semiconductor body 3 comprises or is presently a laser diode with an emission maximum of at most 550 nanometers. Electromagnetic radiation emitted by the semiconductor body 3 is emitted through an exit facet 31. The semiconductor body 3 is mounted on a submount 7, which is directly connected to the carrier 2 via a connection site 5. In other words, the semiconductor body 3 is connected to the carrier 2 via the connection site 5. It is also possible that a further connection site 5 is arranged between the semiconductor body 3 and the submount 7. Alternatively, the semiconductor body 3 is connected directly to the carrier 2 via the connection site 5. In this case, no submount 7 is arranged between semiconductor body 3 and carrier 2.

The connection site 5 comprises metallic nanostructures. The metallic nanostructures are nanowires. Presently, the nanowires comprise a distance of at most 1 micrometer or the nanowires touch each other at least partially. In particular, the nanowires are interlocked. A main extension direction of the nanowires is transverse, in particular perpendicular to a main extension plane of the connection site 5. The metallic nanostructures comprise Au, Ag and/or Cu or consist thereof. An alloy is arranged between the metallic nanostructures. The alloy comprises the Au, Ag and/or Cu of the metallic nanostructures and a further constituent. The further constituent of the alloy is selected from the following group: Ga, In, Hg, Sn. The alloy can thus comprise, for example, AuGa, AuIn, AuHg, AgGa, AgIn, AgHg, or CuSn.

The optical element 4 is arranged in a beam path of the semiconductor body 3 of the optoelectronic module 1 of FIG. 1A. In other words, the optical element 4 is arranged on a side of the semiconductor body 3 on which the exit facet 31 is present. The optical element 4 is, for example, a prism, a collimating lens, or a beam splitter. An interposer 8 is arranged between the optical element 4 and the carrier 2. Furthermore, a connection site 5′ is arranged between the interposer 8 and the carrier 2. In other words, the optical element 4 is connected to the carrier 2 via the connection site 5′ between the interposer 8 and the carrier 2. Alternatively, the optical element 4 is connected directly to the carrier 2 via the connection site 5′. This means that no interposer 8 is arranged between the optical element 4 and the carrier 2.

The connection site 5′ between the interposer 8 and the carrier 2 is formed in particular in the same way as the connection site 5 between the submount 7 and the carrier 2. Alternatively, the connection site 5′ comprises metallic nanostructures and/or an alloy of a different material than the connection site 5. The metallic nanostructures of the connection site 5′ comprise Au, Ag and/or Cu. The alloy of the connection site 5′ comprises the Au, Ag and/or Cu of the metallic nanostructures and a further constituent, such as Ga, In, Hg or Sn. In the present case, the metallic nanostructures are nanowires comprising a main extension direction transverse, in particular perpendicular to a main extension plane of the connection site 5′.

FIG. 1B shows an optoelectronic module 1 in a schematic plan view. In particular, FIG. 1B shows the optoelectronic module 1 of FIG. 1A in plan view. A total of three semiconductor bodies 3, 3′, 3″ are arranged on the carrier 2, which are connected to the carrier 2 via a connection site 5. A submount 7, 7′, 7″ is arranged between the carrier 2 and each of the semiconductor bodies 3, 3′, 3″. The semiconductor bodies 3, 3′, 3″ presently comprise laser diodes. Optical elements 4, 4′, 4″ are located in the beam paths of the semiconductor bodies 3, 3′, 3″. The optical elements 4, 4′, 4″ are connected to the carrier 2 by connection sites 5′. The semiconductor bodies 3, 3′, 3″ differ in the electromagnetic radiation they emit. In particular, the semiconductor body 3 emits electromagnetic radiation from the blue spectral range, the semiconductor body 3′ emits electromagnetic radiation from the red spectral range and the semiconductor body 3″ emits electromagnetic radiation from the green spectral range.

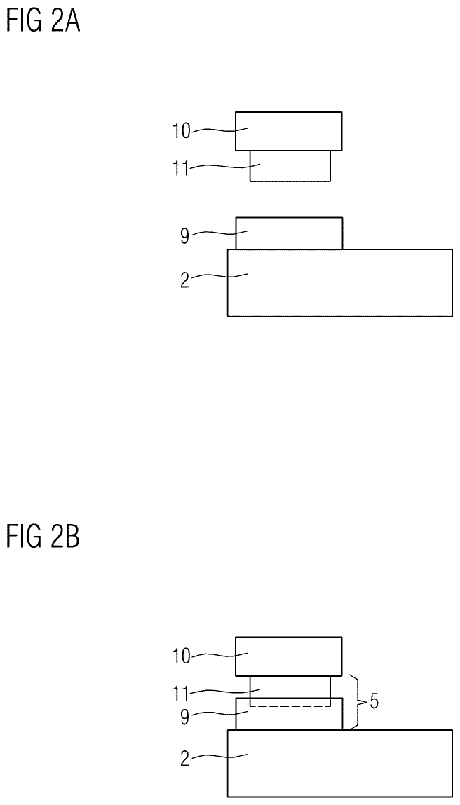

FIGS. 2A and 2B describe a method for producing an optoelectronic module 1 according to an exemplary embodiment. First, a carrier 2 with a first connection element 9 and a component 10 with a second connection element 11 are provided (FIG. 2A). The first connection element 9 at least partially covers the carrier 2. The first connection element 9 and the second connection element 11 comprise metallic nanostructures, preferably nanowires comprising Au. The first connection element 9 on the carrier 2 has a larger extension than the second connection element 11 on the component 10. The metallic nanostructures comprise nanowires which comprise a main extension direction transverse to a main extension direction of the first connection element 9 and/or the second connection element 11.

The component 10 comprises a semiconductor body 3 or an optical element 4. Presently, the component 10 is a lens. The component 10 is actively adjusted with the aid of a gripper. At the same time, during operation of the optoelectronic module 1, an optical output parameter of the optoelectronic module 1 is detected. The component 10 is then aligned and positioned with the gripper using the optical output parameter.

In other words, the component 10 is aligned and positioned while a semiconductor body 3 already arranged on the carrier 2 emits electromagnetic radiation. The component 10 is thereby aligned with the aid of the gripper in such a way that, for example, an intensity of the electromagnetic radiation emitted by the optoelectronic module 1 is maximized.

During the active adjustment of the component 10, the first connection element 9 and the second connection element 11 are pressed or squeezed together. This creates a connection site 5 comprising the first connection element 9 and the second connection element 11, as shown in FIG. 2B. In the connection site 5, the metallic nanostructures of the first connection element 9 and the second connection element 11 interlock or at least partially touch each other.

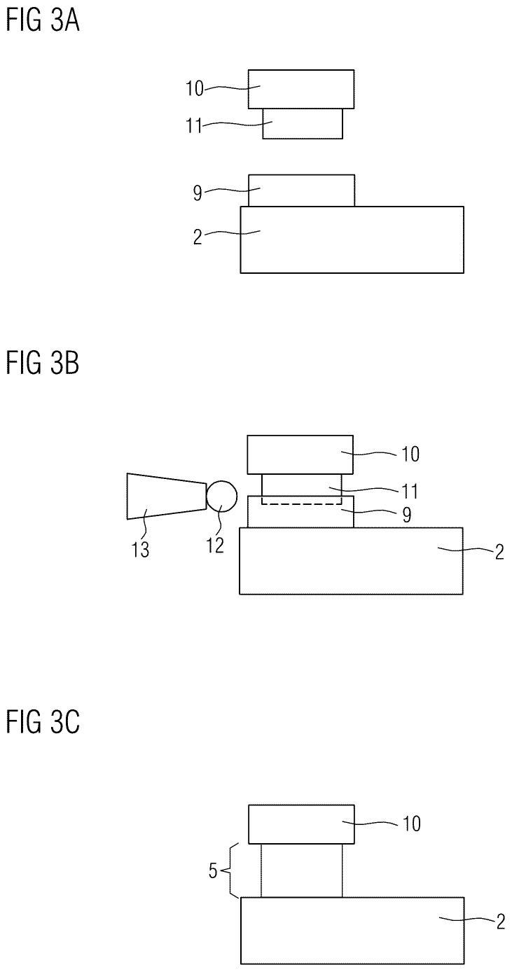

FIGS. 3A to 3C show a further exemplary embodiment of a method for manufacturing an optoelectronic module 1. Analogous to FIG. 2A, a carrier 2 with a first connection element 9 comprising metallic nanostructures is provided (FIG. 3A). Furthermore, a component 10 with a second connection element 11 is provided, which also comprises metallic nanostructures. The first connection element 9 has a larger extension than the second connection element 11. Presently, the metallic nanostructures of the first connection element 9 and the second connection element 11 comprise nanowires with Au. Au comprises a melting temperature of approximately 1064° C. The component 10 presently comprises a lens.

The component 10 is actively adjusted, wherein the first connection element 9 and the second connection element 11 are pressed together, as shown in FIG. 3B. During active adjustment, the component 10 is aligned and/or positioned around six axes. This creates a connection site 5 comprising the first connection element 9 and the second connection element 11. In the connection site, the nanowires of the first connection element 9 and the second connection element 11 comprise a maximum distance of 10 micrometers. A compacting agent 12 is then introduced into the connection site 5. The compacting agent 12 is introduced into the connection site 5 in liquid form, for example with the aid of a dispenser 13. The compacting agent 12 presently comprises Ga or In.

So that the compacting agent 12 can be introduced into the connection site 5 in liquid form, the compacting agent 12 is melted before being introduced into the connection site 5. In particular, Ga comprises a melting temperature of about 30° C., In of about 157° C.

During the introduction of the compacting agent 12 into the connection site 5, the compacting agent 12 is drawn into cavities between the metallic nanostructures of the first connection element 9 and the second connection element 11. In particular, this process is carried out by capillary forces. The compacting agent 12 dissolves part of the material of the metallic nanostructures of the first connection element 9 and the second connection element 9, so that an alloy is formed between the metallic nanostructures. At the same time, a part of the metallic nanostructures remains in the connection site 5. In other words, the connection site 5 comprises the metallic nanostructures of the first connection element 9 and the second connection element 11 as well as the alloy after the introduction of the compacting agent 12. The alloy comprises AuGa or AuIn.

The alloy of the material of the first connection element 9 and the second connection element 11 and the compacting agent 12 comprises a higher melting temperature than the compacting agent 12, in particular a melting temperature of over 260° C. This results in isothermal solidification of the alloy between the metallic nanostructures in the connection site 5, creating a material bond between the component 10 and the carrier 2 (FIG. 3C). The connection site 5 is stable at a temperature of about 260° C., as none of the materials in the connection site 5 melts below this temperature. This makes the connection SMD-solderable.

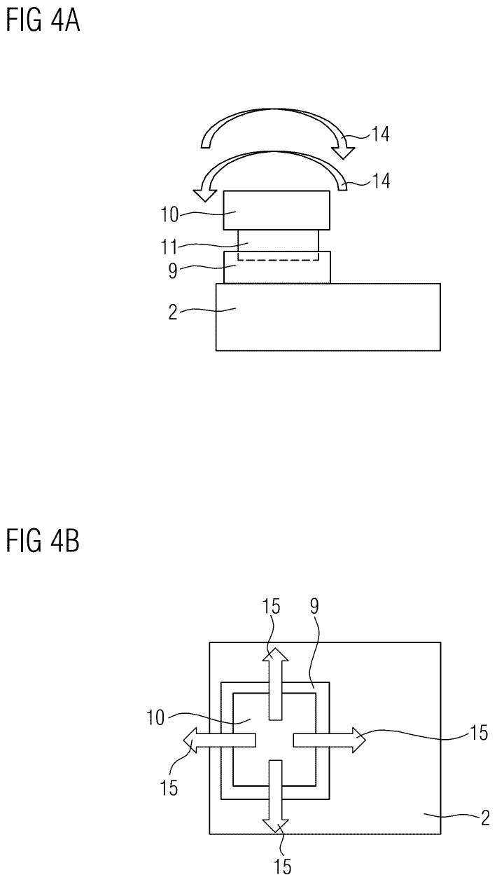

FIG. 4A shows a schematic sectional view of a step of a method for producing an optoelectronic module 1 according to an exemplary embodiment. Presently, a first connection element 9 is applied on the carrier 2 and a second connection element 11 is applied on the component 10. The second connection element 11 comprises a smaller extension than the first connection element 9. Furthermore, the second connection element 11 has a smaller extension than the component 10. In other words, the second connection site 11 covers only a part of the surface of the component 10, via which the component 10 is connected to the carrier 2. During active adjustment, the component 10 is aligned about one of its main axes by rotation. The rotation takes place in particular along the rotation directions 14.

It is also possible to tilt the component 10 in two different directions during active adjustment and/or to rotate it about a light propagation direction. Rotation about the direction of light propagation is used, for example, if the component 10 is a semiconductor body, in particular with a non-rotationally symmetrical radiation characteristic.

FIG. 4B shows a plan view of the step of the method for producing an optoelectronic module 1 shown in FIG. 4A. The first connection element 9 on the carrier 2 comprises a larger extension than the component 10. During active adjustment, the component 10 is positioned along the displacement direction 15. The displacement direction 15 are parallel to a main extension plane of the carrier 2 and/or the component 10. In addition, during active adjustment, vertical positioning takes place, i.e. positioning perpendicular to the main extension plane of the carrier 2.

The features and exemplary embodiments described in connection with the figures may be combined with one another in accordance with further exemplary embodiments, even if not all combinations are explicitly described. Furthermore, the exemplary embodiments described in connection with the figures may alternatively or additionally comprise further features as described in the general part.

The invention is not limited to the exemplary embodiments by the description thereof. Rather, the invention comprises any new feature as well as any combination of features, which includes in particular any combination of features in the patent claims, even if this feature or combination itself is not explicitly stated in the patent claims or exemplary embodiments.

1.-18. (canceled)

19. An optoelectronic module comprising:
a carrier;
a radiation-emitting semiconductor body arranged on the carrier; and
an optical element in a beam path of the semiconductor body,
wherein at least the optical element is connected to the carrier via a connection site comprising metallic nanostructures.

20. The optoelectronic module according to claim 19, wherein the optoelectronic module comprises a housing which hermetically encapsulates at least the semiconductor body.

21. The optoelectronic module according to claim 20, wherein the optoelectronic module is free of organic constituents at least within the housing.

22. The optoelectronic module according to claim 19, wherein the semiconductor body comprises a laser diode.

23. The optoelectronic module according to claim 19, wherein the optoelectronic module comprises at least one further semiconductor body.

24. The optoelectronic module according to claim 19, wherein the optical element comprises a lens, a prism, a collimating lens, a beam a combiner, a polarizing filter, a birefringent crystal, or a photonic integrated circuit.

25. The optoelectronic module according to claim 19,
wherein the metallic nanostructures comprise nanowires, and
wherein the nanowires comprise a distance of at most 10 micrometers.

26. The optoelectronic module according to claim 25, wherein the nanowires touch each other at least partially.

27. The optoelectronic module according to claim 19, wherein the metallic nanostructures comprise at least one metal selected from the group consisting of Au, Ag and Cu.

28. The optoelectronic module according to claim 19, further comprising an alloy including the metal of the nanostructures arranged between the metallic nanostructures.

29. The optoelectronic module according to claim 28, wherein a further constituent of the alloy is selected from the group consisting of Ga, In, Hg and Sn.

30. A method for producing an optoelectronic module, the method comprising:
providing a carrier with a first connection element comprising metallic nanostructures;
providing a component with a second connection element comprising metallic nanostructures;
actively adjusting the component on the carrier; and
connecting the carrier and the component,
wherein a connection site comprising the first connection element and the second connection element is formed, and
wherein the component is an optical element.

31. The method according to claim 30, wherein the connection site is stable at a temperature of at least 250° C.

32. The method according to claim 30,
wherein a compacting agent is introduced into the connection site while connecting the carrier and the component, and
wherein the compacting agent forms an alloy with a material of the first connection element and the second connection element.

33. The method according to claim 32, wherein the compacting agent is melted before introducing into the connection site.

34. The method according to claim 32, wherein the compacting agent is selected from the group consisting of Ga, In, Hg, Sn and alloys thereof.

35. The method according to claim 30, wherein an extension of the first connection element is larger than an extension of the second connection element.

36. An optoelectronic module comprising:
a carrier;
a radiation-emitting semiconductor body arranged on the carrier; and
an optical element in a beam path of the semiconductor body,
wherein at least one of the semiconductor body or the optical element is connected to the carrier via a connection site comprising metallic nanostructures.
